(19) United States
(12) Patent Application Publication
(10) Pub. No.: US 2011/0133731 A1
(43) Pub. Date: Jun. 9, 2011

(54) METHOD AND DEVICE FOR MAGNETIC INDUCTION TOMOGRAPHY

(75) Inventors: Marko Johannes Vauhkonen, Kuopio (FI); Claudia Hannelore Igney, Aachen (DE); Matthias Hamsch, Aachen (DE); Robert Pinter, Aachen (DE)

(73) Assignee: KONINKLIJKE PHILIPS ELECTRONICS N.V., EINDHOVEN (NL)

(21) Appl. No.: 13/058,981

(22) PCT Filed: Aug. 7, 2009
(86) PCT No.: PCT/IB2009/053460

§ 371 Date: Feb. 14, 2011

(30) Foreign Application Priority Data
Aug. 20, 2008 (CN) 200810211035.4

(51) Int. Cl. G01R 33/12

(52) U.S. Cl. 324/239

(57) ABSTRACT

This invention relates to a method and device for magnetic induction tomography. The device comprises a transmitting coil arrangement for generating a primary magnetic field, the primary magnetic field inducing an eddy current in an object of interest, and a measurement coil arrangement for measuring a secondary magnetic field generated by the eddy current to generate a set of measurement data used for image reconstruction of the object of interest, wherein the transmitting coil arrangement at least comprises a pair of transmitting coils intended for carrying substantially electrical currents flowing in the same direction and positioned symmetrically along a common axis and the measurement coil arrangement at least comprises a pair of measurement coils connected and positioned symmetrically along the axis. In an embodiment, the pair of transmitting coils and the pair of measurement coils are respectively Helmholtz coils.

### FIELD OF THE INVENTION

The invention relates to magnetic induction tomography, particularly to specific coil arrangements for a magnetic induction tomography scanner.

### BACKGROUND OF THE INVENTION

Magnetic induction tomography (MIT) is a noninvasive and contactless imaging technique with applications in industry and medical imaging. In contrast to other electrical imaging techniques, MIT does not require direct contact of the sensors with the object of interest for imaging.

MIT is used to reconstruct the spatial distribution of the passive electrical properties inside the object of interest, for example, conductivity σ, permittivity ε and permeability μ. In MIT, sinusoidal electric current, normally between a few kHz up to several MHz, is applied to a transmitting coil, generating a time varying magnetic field. This is normally called the primary magnetic field. Due to the conducting object of interest, for example a biological tissue, the primary field produces eddy currents in the object of interest. These eddy currents generate the secondary magnetic field. The combination of these magnetic fields induces voltages in the receiving coils. Using several transmitting coils and repeating the measurements, sets of measurement data are taken and used to visualize changes in time of the electromagnetic properties of the object. MIT is sensitive to all three passive electromagnetic properties: electrical conductivity, permittivity and magnetic permeability. As a result, for example, the conductivity contribution in the object of interest can be reconstructed. In particular, MIT is suitable for examination of biological tissue, because of the magnetic permeability value of such tissue μ_{R}≈1.

Prior art patent application WO2007072343 discloses a magnetic induction tomography system for studying the electromagnetic properties of an object. The system comprises: one or more generator coils adapted for generating a primary magnetic field, said primary magnetic field inducing an eddy current in the object; one or more sensor coils adapted for sensing a secondary magnetic field, said secondary magnetic field being generated as a result of said eddy current; and means for providing a relative movement between one or more generator coils and/or one or more sensor coils, on the one hand, and the object to be studied, on the other hand.

However, the sensitivity in the centre of the object of interest is not very good with existing MIT technology. This is due to the fact that the transmitting coils and the measurement coils for detection are positioned around the object of interest while the fields are not focused in the center of the object of interest and therefore the sensitivity near the surface of the object is higher than that in the center of the object. That becomes a problem when information about the central part of the object is of interest.

### SUMMARY OF THE INVENTION

According to one embodiment of the invention, a device that improves the sensitivity of MIT in a central part of an object of interest is provided. The device comprises:
a transmitting coil arrangement for generating a primary magnetic field, the primary magnetic field inducing an eddy current in an object of interest; and
a measurement coil arrangement for measuring a secondary magnetic field generated by the eddy current to generate a set of measurement data used for imaging reconstruction of the object of interest;
   wherein the transmitting coil arrangement at least comprises a pair of transmitting coils carrying substantially equal electrical currents flowing in the same direction and positioned symmetrically along a common axis, and wherein the measurement coil arrangement at least comprises a pair of measurement coils connected and positioned symmetrically along the axis.

It is advantageous for the pair of transmitting coils and the pair of measurement coils to be respective Helmholtz coils.

By replacing conventional transmitting coils and measurement coils with Helmholtz coils or coils arranged substantially close to Helmholtz coils, fairly homogenous but still localized sensitivity distribution inside the object of interest can be achieved.

It is also advantageous for the pair of transmitting coils and the pair of measurement coils to be arranged along the axis. The distance between the pair of transmitting coils and the pair of measurement coils is determined such that the maximum current density of eddy current in the object of interest generated by the pair of transmitting coils and the distribution of the maximum sensitivity of the pair of measurement coils are overlapped.

By overlapping the maximum current density of eddy current and the distribution of maximum sensitivity of the pair of measurement coils, the sensitivity in the center of the object of interest is maximized.

According to another embodiment of the invention, this invention further provides a method that improves the sensitivity of MIT in a central part of an object of interest. The method comprises the steps of:
generating a primary magnetic field by a transmitting coil arrangement, the transmitting coil arrangement at least comprising a pair of transmitting coils carrying substantially equal electrical currents flowing in the same direction and positioned symmetrically along a common axis, the primary magnetic field inducing an eddy current in an object of interest; and
measuring a secondary magnetic field generated by the eddy current to generate a set of measurement data used for imaging reconstruction of the object of interest, the measurement coil arrangement at least comprising a pair of measurement coils connected and positioned symmetrically along the axis.

Detailed explanations and other aspects of the invention will be given below.

### DESCRIPTION OF THE DRAWINGS

The above and other objects and features of the present invention will become more apparent from the following detailed description considered in connection with the accompanying drawings, in which:

FIG. 1 depicts an exemplary embodiment of the device in accordance with the invention.

FIGS. 2a and 2b depict a distribution of current density of the eddy current generated by the transmitting coils in accordance with the invention.

FIGS. 3a and 3b depict a distribution of sensitivity of the measurement coils in accordance with the invention.

FIGS. 4a, 4b, 4c and 4d depict how to position the transmitting coils and the measurement coils in accordance with the invention.

FIGS. 5a and 5b depict the coil arrangement with resulting sensitivity line used for measurement in accordance with the invention.

FIGS. 6a and 6b depict how to obtain multiple sets of measurements in accordance with the invention.

FIG. 7 depicts an exemplary embodiment of the device in accordance with the invention.

FIGS. 8a and 8b further depict another exemplary embodiment of the device in accordance with the invention.

FIG. 9 depicts a flowchart of a method according to the invention.

The same reference numerals are used to denote similar parts throughout the figures.

### DETAILED DESCRIPTION

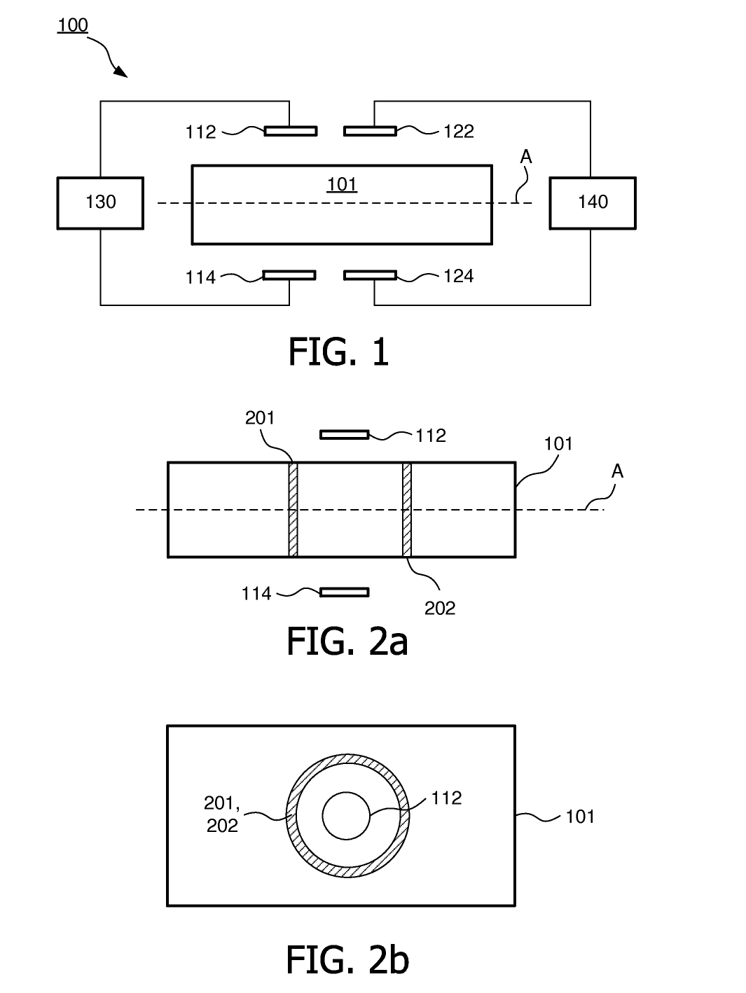

FIG. 1 depicts an exemplary embodiment of the device in accordance with the invention.

According to the invention, the device 100 comprises a transmitting coil arrangement, which comprises a pair of transmitting coils 112, 114 that are positioned symmetrically along a common axis A, e.g. the two transmitting coils are placed at two sides of an object of interest 101. The object of interest 101 is an object to be measured, for example, the head of a human being, or any other conductive material.

The transmitting coils 112, 114 are intended for carry substantially equal electrical current flowing in the same direction to generate a primary magnetic field. As shown in FIG. 1, the pair of transmitting coils 112 and 114 is provided with an excitation signal, e.g., an alternating current generated by a source 130, for generating a primary magnetic field. The primary magnetic field induces an eddy current in the object of interest 101. The eddy current generates an alternating magnetic field, which is called a secondary magnetic field.

In an embodiment, the pair of transmitting coils 112, 114 can be connected to ensure the electrical currents are substantially equal and flowing in the same direction.

The device further comprises a measurement coil arrangement, which comprises a pair of measurement coils 122, 124 that are connected. The two measurement coils are positioned symmetrically along axis A, similar to the transmitting coils.

The measurement coils 122, 124 are arranged for measuring signals induced by the secondary magnetic fields to generate a set of measurement data for image reconstruction. As the secondary magnetic field generated by the eddy current, it carries information about the inside of the object of interest, for example, the conductivity distribution of a tissue of a human head or any other conductive material.

The signals induced by the secondary magnetic field are induced voltages. As the voltage induced by the secondary magnetic field is very small relative to the voltage induced by the primary magnetic field, it is difficult to extract the voltage induced by the secondary magnetic field directly, given the strong background magnetic field.

Among a number of measurement techniques discussed in prior art documents, one approach is to measure the voltage change from a reference measurement. The measured voltage change indicates the change of the secondary magnetic field generated by the eddy current and thus can be used for difference imaging to visualize the change of the conductivity distribution in the object of interest.

The device further comprises a processor 140 for reconstructing images based on the set of measurement data. The image reconstruction may follow the method of conductivity calculations and image reconstruction that is described in the prior art document “Image reconstruction approaches for Philips magnetic induction tomography”, M. Vauhkonen, M. Hamsch and C. H. Igney, ICEBI 2007, IFMBE Proceedings 17, pp. 468-471, 2007. The image reconstruction, e.g. the calculation of conductivity distribution in the object of interest can be advantageously implemented by a software program embedded in the processor.

It is advantageous for the pair of transmitting coils 112, 114 and the pair of measurement coils 122, 124 to be respective Helmholtz coils.

It is well known that Helmholtz coils consist of two identical circular magnetic coils that are placed symmetrically one on each side of the experimental area, i.e. the object of interest, along a common axis, and separated by a distance h equal to the radius R of the coils. Each coil carries an equal electrical current flowing in the same direction. Optionally, the Helmholtz coils can be electrically connected so that their currents flow in the same direction (the connection may be either serial or parallel).

It is should be noticed that the size and the shape of the object of interest depicted in FIG. 1 and other figures in this invention are only for the purpose of description and can be adapted to any size and/or shape for different applications.

FIGS. 2a and 2b depicts a distribution of current density of the eddy current generated by the transmitting coils in accordance with the invention. FIG. 2a shows a side view and FIG. 2b shows a top-view.

A pair of circular coils 112, 114 (Helmholtz coils), working as transmitting coils, are positioned symmetrically along axis A, e.g. are placed at two sides of the object of interest 101, assuming the object of interest 101 is a homogeneous tissue block with constant conductivity. When the two transmitting coils are fed with substantially equal electrical current flowing in the same direction, two thin linear areas are generated in the object of interest that represent maximum current density of the eddy current produced by the transmitting coils. The linear areas go through the object of 101 between the coils and are indicated by lines 201, 202.

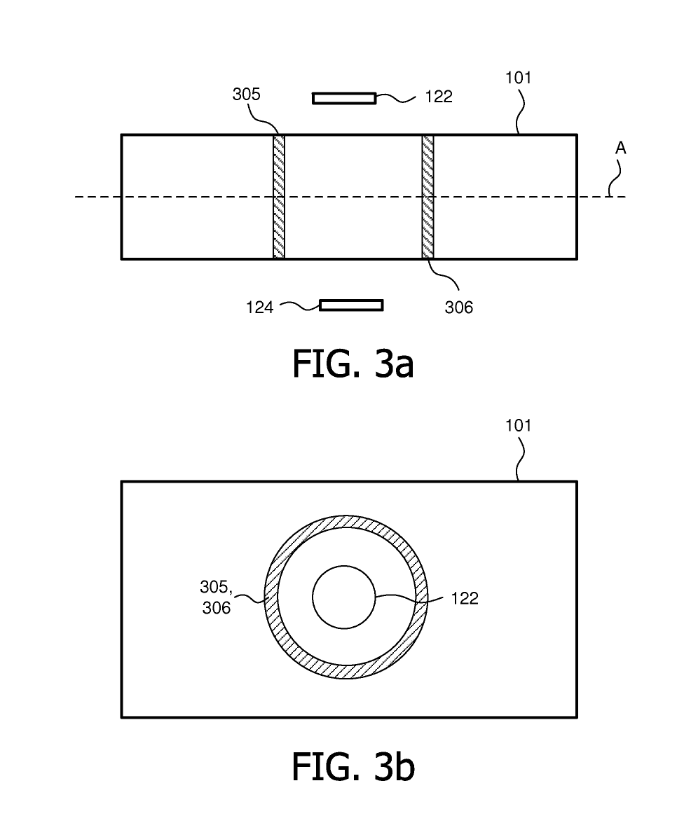

FIGS. 3a and 3b depict a distribution of sensitivity of the measurement coils in accordance with the invention. FIG. 3a shows a side view and FIG. 3b shows a top-view.

A pair of circular coils 122, 124 (Helmholtz coils) working as measurement coils, is positioned in symmetrically along axis A, e.g. they are placed at two sides of the tissue block. The linear areas indicated by lines 305, 306 are formed that represent maximum sensitivity areas of the measurement coils, e.g., the measurement coils have high sensitivity in the area along the lines 305, 306.

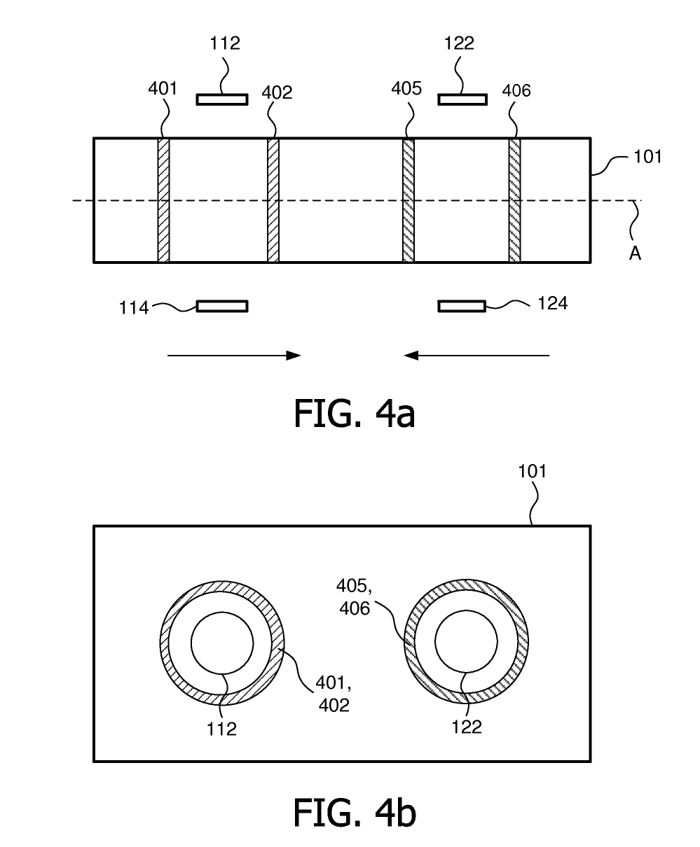

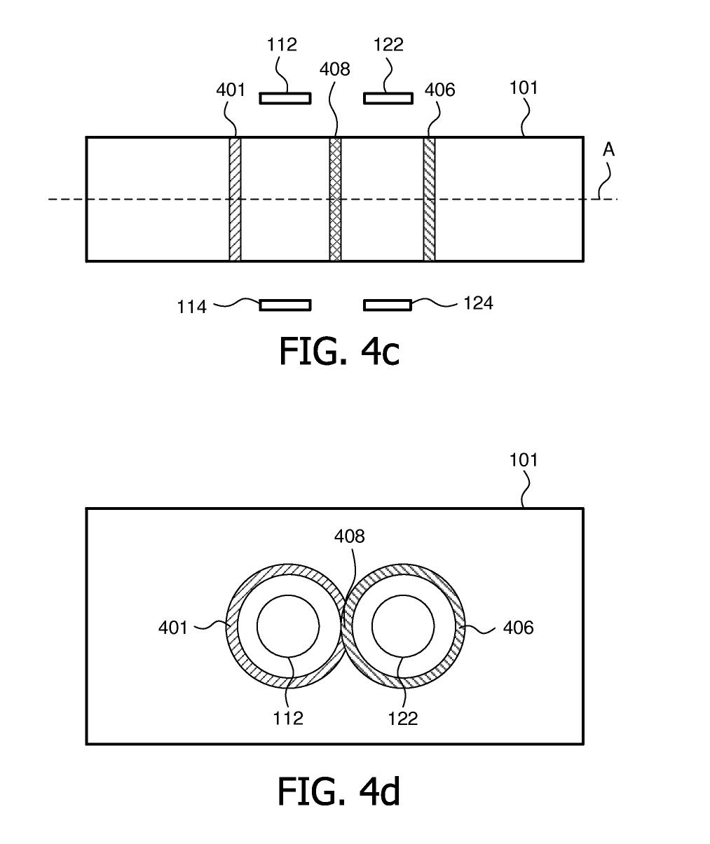

FIGS. 4a, 4b, 4c and 4d depict how to position the transmitting coils and the measurement coils in accordance with the invention. FIGS. 4a and 4c are side views and FIGS. 4b and 4d are top views.

As shown in FIGS. 4a and 4b, Helmholtz coils 112, 114 for transmitting and Helmholtz coils 122, 124 for measurement are positioned along axis A, e.g., side by side at two sides of the object of interest. Accordingly, a distribution of maximum current density of the eddy current produced by the transmitting coils 112, 114 is generated and indicated by two lines 401, 402, and meanwhile, a distribution of maximum sensitivity of the measurement coils is formed that is indicated by two lines 405, 406.

When transmitting coils 112, 114 and measurement coils 122, 124 are placed inwards, e.g. along axis A in the arrowhead directions as shown in FIG. 4a, the linear areas indicated by line 402 and 405 are overlapped and merged to one line 408, as shown in FIGS. 4c and 4d. The distance between the pair of transmitting coils and the pair of measurement coils is thus determined such that the distribution of the maximum current density of eddy current in the object of interest generated by the pair of transmitting coils 112, 114 and the distribution where we expect the maximum sensitivity of the pair of measurement coils 122, 124 have an overlapped area.

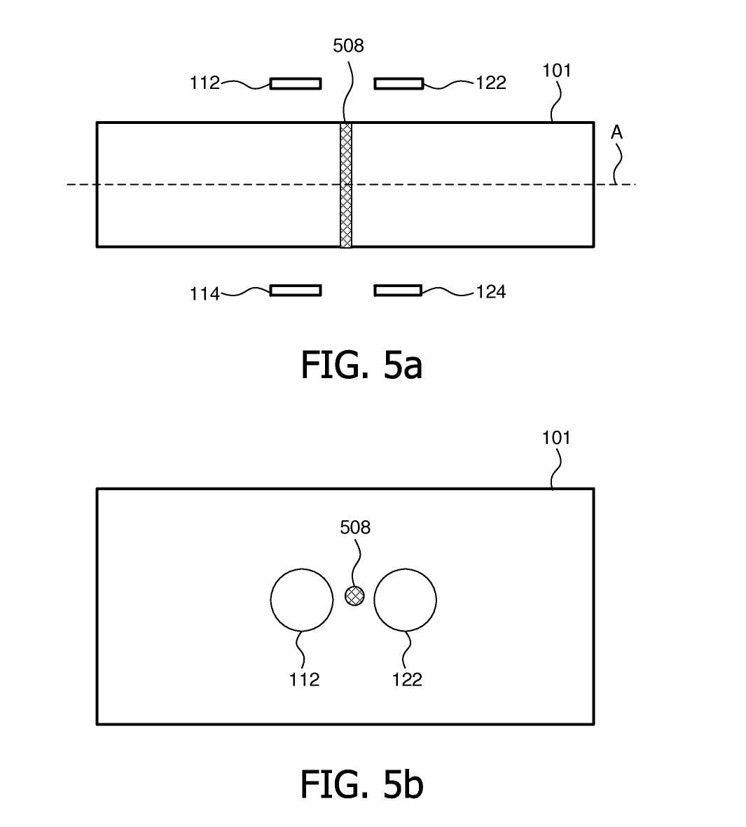

FIGS. 5a and 5b depict the coil arrangement with resulting sensitivity line used for measurement. FIG. 5a is a side view and FIG. 5b is a top view.

There is only one linear area, e.g., line 508, which represents the overlap of the expected maximum sensitivity of the measurement coils and the maximum current density of eddy current generated by the transmitting coils, and thus is of concern for efficient measurement of the secondary magnetic field generated by the eddy current. So for measurement, the measurement data mainly comprises the information of signals from this area.

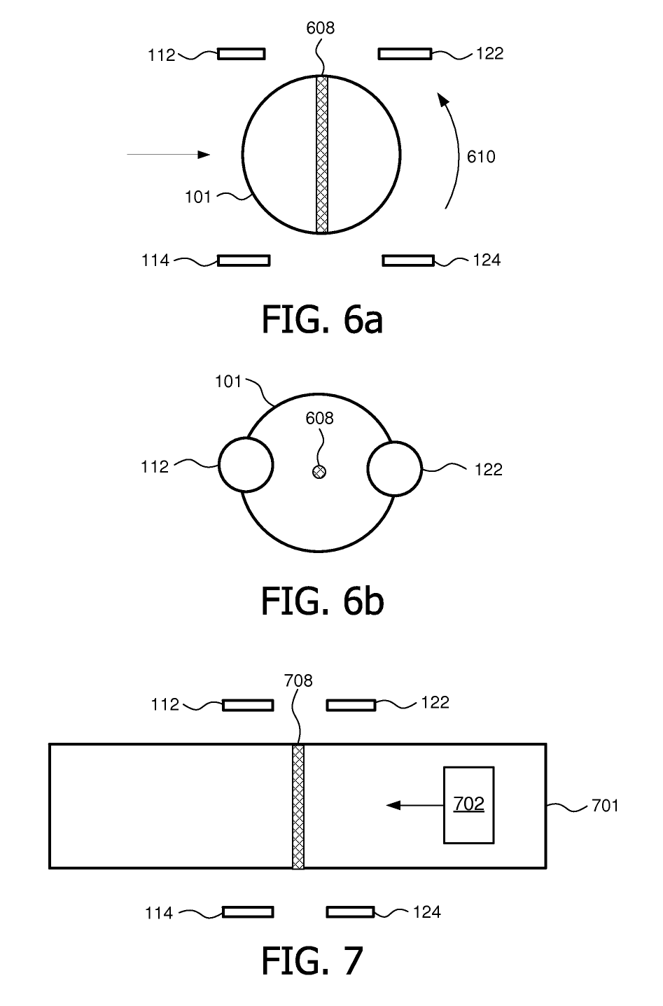

FIG. 6 depicts an embodiment to obtain multiple sets of measurements in accordance with the invention. FIG. 6a is a side view and FIG. 6b is a top view.

As shown in FIGS. 6a and 6b, the coils arrangement has the maximum sensitivity distribution in the area indicated by 608. When providing a relative movement between the coils arrangements (112, 114, 122, 124) and the object of interest 101, for example, making the object rotate relative to the coils arrangement rotating [??] along the arrowhead 610, a plurality of sets of measurement data can be collected for image reconstruction.

It is also appreciated by those skilled in the art that the device in accordance with the invention may comprise means (not shown in the figures) for providing such a relative movement between the coils arrangement and the object of interest.

It is appreciated by those skilled in the art that the transmitting arrangement and/or the measurement arrangement may comprise a plurality of Helmholtz coils to speed up the measurement procedure.

FIG. 7 depicts an exemplary embodiment of a scanner comprising the device in accordance with the invention.

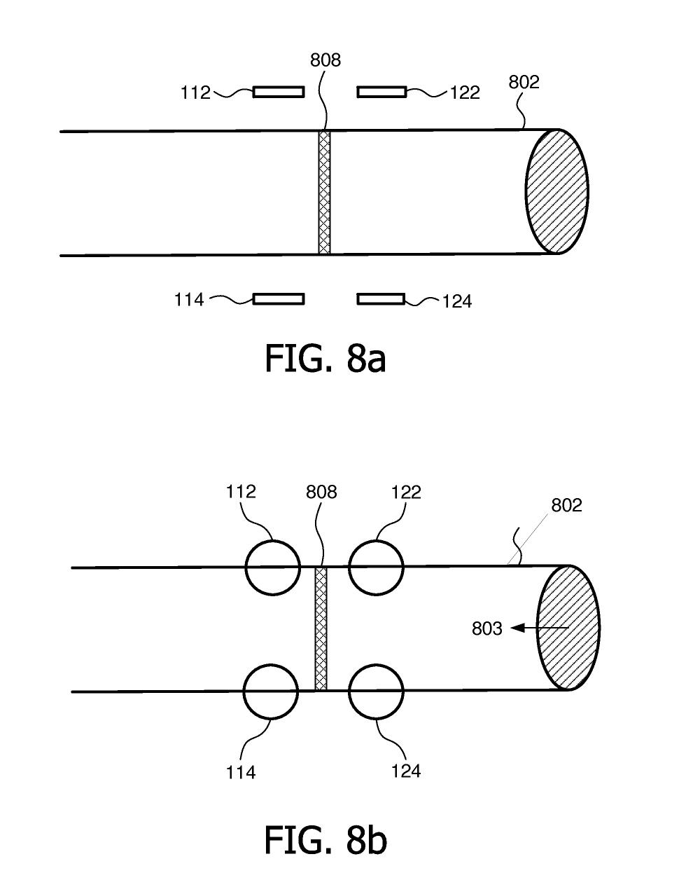

As shown in FIG. 7, the coil arrangements having maximum sensitivity distribution in the area 708 are incorporated in a scanner used for scanning objects, for example, the luggage in an airport. The luggage 702 is put on a belt 701. When the luggage is moving along the belt and through the area 708, the scanner generates a set of measurement data for image reconstruction so as to determine whether the luggage 702 comprises the object having specific conductivities. FIGS. 8a and 8b depict another exemplary embodiment of a scanner comprising the device in accordance with the invention. FIG. 8a is a side view and FIG. 8b is a top view.

As shown in FIGS. 8a and 8b, the coil arrangements having maximum sensitivity distribution in the area 808 are incorporated with a scanner 802, which is shaped as a tub and which liquids can pass through along direction 803. When liquid passes through the area 808, a set of measurement data can be collected for examining the conductivity of the liquid.

It is appreciated by those skilled in the art that the scanners described in FIG. 7 and FIGS. 8a/8b may have different applications for scanning objects/liquids or testing the conductivity in the scanned objects/liquids.

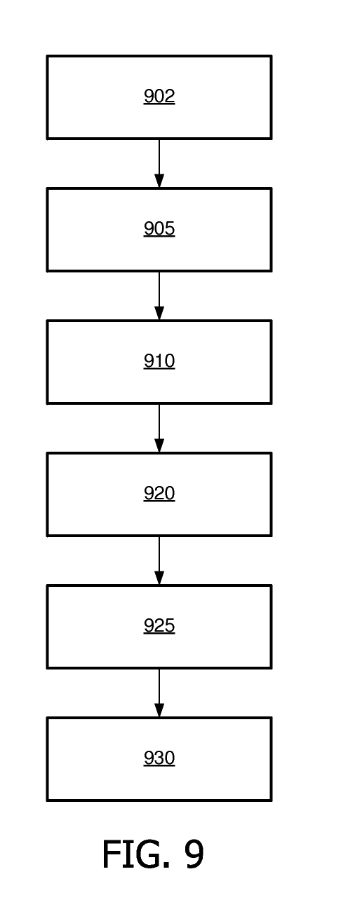

FIG. 9 depicts a flowchart of a method according to the invention.

According to the invention, the method of magnetic induction tomography comprises a step 910 of generating a primary magnetic field by providing an excitation signal to a transmitting coil arrangement. The transmitting coil arrangement comprises a pair of transmitting coils 112, 114 intended for carrying substantially equal electrical current flowing in the same direction. The two transmitting coils are positioned symmetrically along a common axis A. The primary magnetic field induces an eddy current in an object of interest that generates a secondary magnetic field.

The method further comprises a step 920 of measuring signals induced by the secondary magnetic fields to generate a set of measurement data by using a measurement coil arrangement. The measurement coil arrangement comprises a pair of measurement coils 122, 124 that are connected and positioned symmetrically along axis A. In an embodiment, the pair of transmitting coils 112, 114 and the pair of measurement coils 122, 124 are respective Helmholtz coils.

The method further comprises a step 930 of reconstructing an image representing conductivity distribution of the object of interest based on the set of measurement data obtained in step 920.

It is advantageous for the method to further comprise a step 902 of positioning the pair of transmitting coils and the pair of measurement coils along the axis A and a step 905 of determining the distance between the pair of transmitting coils and the pair of measurement coils such that the distribution of the maximum current density of eddy current in the object of interest generated by the pair of transmitting coils and the distribution of the maximum sensitivity of the pair of measurement coils have an overlapped area.

It is advantageous for the method to further comprise a step 925 of providing a relative movement between the coils arrangement and the object of interest so as to collect a plurality of sets of measurement data for image reconstruction.

It should be noted that the above-mentioned embodiments illustrate rather than limit the invention and that those skilled in the art will be able to design many alternative embodiments without departing from the scope of the appended claims. In the claims, any reference symbols placed between parentheses shall not be construed as limiting the claim. Use of the verb “comprise” and its conjugations does not exclude the presence of elements or steps other than those stated in a claim. Use of the indefinite article “a” or “an” preceding an element does not exclude the presence of a plurality of such elements. The invention can be implemented by means of hardware comprising several distinct elements and by means of a suitably programmed computer. In the device claims enumerating several units, several of these units can be embodied by one and the same item of hardware or software. Use of the words “first”, “second” and “third”, etc. does not indicate any ordering. These words are to be interpreted as names.

1. A device for magnetic induction tomography, comprising:
a transmitting coil arrangement (112, 114) for generating a primary magnetic field, the primary magnetic field inducing an eddy current in an object of interest; and
a measurement coil arrangement (122, 124) for measuring a secondary magnetic field generated by the eddy current to generate a set of measurement data used for image reconstruction of the object of interest;
wherein the transmitting coil arrangement at least comprises a pair of transmitting coils (112, 114) intended for carrying substantially equal electrical current flowing in the same direction and positioned symmetrically along a common axis (A), and wherein the measurement coil arrangement at least comprises a pair of measurement coils (122, 124) connected and positioned symmetrically along the axis (A).

2. A device as claimed in claim 1, wherein the pair of transmitting coils (112, 114) and the pair of measurement coils (122, 124) are respective Helmholtz coils.

3. A device as claimed in claim 1, wherein the pair of transmitting coils (112, 114) and the pair of measurement coils (122, 124) are arranged along the axis (A).

4. A device as claimed in claim 3, wherein the distance between the pair of transmitting coils (112, 114) and the pair of measurement coils (122, 124) is determined such that the distribution of the maximum current density of eddy current in the object of interest generated by the pair of transmitting coils and the distribution of the maximum sensitivity of the pair of measurement coils have overlapped area.

5. A device as claimed in claim 4, wherein the position of the overlapped area is between the pair of transmitting coils (112, 114) and the pair of measurement coils (122, 124).

6. A device as claimed in claim 5, further comprising:
means for providing a relative movement between the coils arrangement and the object of interest so as to collect a plurality of sets of measurement data for image reconstruction and
a processor for reconstructing images of the object of interest based on the set(s) of measurement data.

7. A magnetic induction tomography scanner comprising a device as claimed in claim 1.

8. A method of magnetic induction tomography, comprising the steps of:
generating (910) a primary magnetic field by a transmitting coil arrangement, the transmitting coil arrangement at least comprising a pair of transmitting coils (112, 114) intended for carrying substantially equal electrical current flowing in the same direction and positioned symmetrically along a common axis (A), the primary magnetic field inducing an eddy current in an object of interest; and
measuring (920) a secondary magnetic field generated by the eddy current to generate a set of measurement data used for image reconstruction of the object of interest, the measurement coil arrangement at least comprising a pair of measurement coils (122, 124) connected and positioned symmetrically along the axis (A).

9. A method as claimed in claim 8, wherein the pair of transmitting coils (112, 114) and the pair of measurement coils (122, 124) are respective Helmholtz coils.

10. A method as claimed in claim 8 further comprising a step (902) of positioning the pair of transmitting coils (112, 114) and the pair of measurement coils (122, 124) along the axis.

11. A method as claimed in claim 10 further comprising a step (905) of determining the distance between the pair of transmitting coils (112, 114) and the pair of measurement coils (122, 124) such that the distribution of the maximum current density of eddy current in the object of interest generated by the pair of transmitting coils and the distribution of the maximum sensitivity of the pair of measurement coils have overlapped area.

12. A method as claimed in claim 11 further comprising a step (925) of providing a relative movement between the coils arrangement and the object of interest so as to collect a plurality of sets of measurement data for image reconstruction.

13. A method as claimed in claim 12 further comprising a step (930) of reconstructing images of the object of interest based on the set(s) of measurement data.
